(19) United States
(12) Patent Application Publication
(10) Pub. No.: US 2019/0295937 A1
(43) Pub. Date: Sep. 26, 2019

(54) NON-ROUGHENED CU TRACE WITH ANCHORING TO REDUCE INSERTION LOSS OF HIGH SPEED IO ROUTING IN PACKAGE SUBSTRATE

(71) Applicant: Intel Corporation, Santa Clara, CA (US)

(72) Inventors: Chong ZHANG, Chandler, AZ (US); Ying WANG, Chandler, AZ (US); Cheng XU, Chandler, AZ (US); Hongxia FENG, Chandler, AZ (US); Meizi JIAO, Chandler, AZ (US); Junnan ZHAO, Gilbert, AZ (US); Yikang DENG, Chandler, AZ (US)

(21) Appl. No.: 15/927,047

(22) Filed: Mar. 20, 2018

(51) Int. Cl. H01L 23/498; C23C 18/26; H05K 1/11; H01L 23/00; H01L 21/48

(52) U.S. Cl. CPC H01L 23/49838; C23C 18/26; H05K 1/113; H01L 24/13; H05K 3/3452; H01L 21/485; H01L 23/49827; H01L 2924/15151; H01L 2924/01029; H01L 24/16

(57) ABSTRACT

Embodiments include semiconductor packages and a method of forming the semiconductor packages. A semiconductor package includes a trace disposed on a conductive layer. The semiconductor package has one or more adhesion anchoring points and a plurality of portions on the trace. An adhesion anchoring point is between two portions on the trace. A surface roughness of an adhesion anchoring point is greater than a surface roughness of a portion on the trace. The trace may be a high-speed input/output (HSIO) trace. The semiconductor package may include via pads disposed on each end of the trace, and a dielectric disposed on the trace. The dielectric is patterned to form openings on the dielectric that expose second portions on the trace. The dielectric remains over the portions. The semiconductor package may have a chemical treatment disposed on the exposed openings on the trace to form the adhesion anchoring points.

### FIELD

Embodiments relate to packaging semiconductor devices. More particularly, the embodiments relate to semiconductor packages having a non-roughened conductive trace with adhesion anchoring points to reduce insertion loss of high-speed input/output (HSIO) routing.

### BACKGROUND

Packaging of semiconductor devices present several problems. One of the main problems with packaging semiconductor devices includes reducing trace roughness in a package substrate without using adhesion promotion to reduce substrate insertion loss. As the high speed IO nyquist frequency requirement increases for semiconductor devices, the insertion loss of the transmission line in the package substrate also increases.

The insertion loss is defined as power ratio of transmitted signal to incident signal, which has multiple components including dielectric loss, conductor loss, and radiation loss. Radiation loss of a stripline transmission line can typically be neglected. To maintain the insertion loss, for example, at roughly 3 dB, a package substrate may have multiple path finding undertakings that focus on the combined reduction of dielectric loss and conductor loss.

Reducing the roughness of a trace is vital for reducing insertion loss on a package substrate. Some packaging solutions to reduce trace roughness may include adhesion promotion and chemical adhesion. Adhesion promotion typically includes finely roughening the Cu surface followed by an organic layer coating. The organic layer coating has functional groups where one end of the coating adheres to the Cu and the other end adheres to the dielectric material, which is generally known as chemical adhesion.

These packaging solutions, however, are limited in size as the minimum roughness achieved by adhesion promotion is roughly 100-150 nm. In addition, the chemical adhesion contributed by the organic coating is only applicable to dielectrics, and the organic coating layer may thus not be applicable for next generation dielectric materials (i.e., organic coating layer modification or development is necessary for the accompanied change of the dielectric materials). Applying the organic coating layer may include both thin and thick coating layers that may reduce adhesion from the adhesion promotion development, as the wet process used in substrate manufacturing to precisely control such thicknesses of the organic coating layers is complicated and challenging.

### BRIEF DESCRIPTION OF THE DRAWINGS

Embodiments described herein illustrated by way of example and not limitation in the figures of the accompanying drawings, in which like references indicate similar features. Furthermore, some conventional details have been omitted so as not to obscure from the inventive concepts described herein.

FIG. 1 is a plan view of a semiconductor package having a conductive layer with a high-speed input/output (HSIO) trace with a plurality of non-roughened portions and one or more adhesion anchoring points, according to one embodiment.

FIGS. 2A-2D are cross-sectional views and plan views, respectively, of a process flow to form a semiconductor package having a conductive layer that includes a HSIO trace with a plurality of non-roughened portions and one or more adhesion anchoring points, according to some embodiments.

FIG. 3 is a cross-sectional view of a semiconductor package including a substrate that has a conductive layer that includes a HSIO trace with a plurality of non-roughened portions and one or more adhesion anchoring points, according to one embodiment.

FIG. 4 is a process flow illustrating a method of a semiconductor package that includes a conductive layer having a HSIO trace with a plurality of non-roughened portions and one or more adhesion anchoring points, according to one embodiment.

FIG. 5 is a schematic block diagram illustrating a computer system that utilizes a semiconductor package having a conductive layer that includes a HSIO trace with a plurality of non-roughened portions and one or more adhesion anchoring points, according to one embodiment.

### DETAILED DESCRIPTION

Described herein are systems that include semiconductor packages having a non-roughened conductive trace with adhesion anchoring points to reduce insertion loss of high-speed input/output (HSIO) routing and methods of forming such semiconductor packages. According to some embodiments, the semiconductor package described below and methods of forming such semiconductor package include one or more conductive layers with one or more HSIO traces having selective adhesion anchoring points. For some embodiments, the semiconductor packages described herein reduce trace roughness, such as a roughness roughly similar to the as-plated copper (Cu) trace roughness, to improve the insertion loss performance of that package.

As used herein, a “HSIO trace” may be variously used to refer to at least one of a trace on a conductive layer of a substrate (or semiconductor package/device) that may transmit signals with a frequency of higher than 28 GHz. Embodiments of the HSIO trace described herein may include a roughened portion and a non-roughened portion. As used herein, a “roughened” portion (also referred to as a roughened Cu, a roughened Cu portion, a Cu roughened surface, an adhesion anchoring point, etc.) refers to a Cu surface (e.g., a Cu HSIO trace, a Cu via pad, a Cu routing trace, etc.) having a surface roughness as a property of the Cu surface texture, which is illustrated (or recognized) by an uneven topography as compared to an approximately flat surface (e.g., an as-plated roughly flat surface). For example, a rough surface, such a roughened Cu surface, is typically marked by finely spaced irregularities, protuberances, or ridges.

In addition, as used herein, a “roughened” portion may be subjected to a chemical treatment (also referred to as a chemical surface treatment, a Cu roughening treatment, a roughening process, etc.). For example, the chemical treatment may include chemical compounds, such as acid based compounds, that help to attain improved copper-to-resin adhesion (e.g., a Cu surface to a build-up film, such as an Ajinomoto build-up film (ABF)). For example, the chemical treatment may include any organic acid-type microetching solution that forms a roughened Cu surface. This chemical treatment may facilitate with a uniquely-roughened Cu surface topography to achieve an enhanced Cu-to-resin adhesion.

As used herein, a “non-roughened” portion (or a portion, a non-roughened Cu surface, a Cu portion, a non-roughened Cu portion, etc.) refers to a Cu surface, such as a non-roughened portion on a HSIO trace (e.g., HSIO traces 120-121), that is not disposed/treated with a chemical treatment. For example, the HSIO trace may have a dielectric disposed and patterned on the HSIO trace. The dielectric may be patterned on the HSIO trace to cover one or more first portions of the HSIO trace and expose one or more openings that expose one or more second portions of the HSIO trace. Continuing with the example above, after the dielectric has been disposed and patterned, the chemical treatment may be disposed on the first and second portions of the HSIO trace may, where the one or more first portions are covered with the dielectric and thus not impacted by the chemical treatment. After the disposing the chemical treatment on the HSIO trace, the one or more first portions may be referred to as the non-roughened portions (or the non-roughened Cu portions), where the non-roughened portions may maintain approximately the same surface roughness as the as-plated Cu surface roughness used to form the HSIO trace (e.g., the as-plated Cu surface may have a roughness of roughly 50 nm or less). Likewise, the one or more second portions may be referred to as roughened portions as the second portions were exposed and treated with the chemical treatment. For one embodiment, the non-roughened portions of the HSIO trace may have a roughness of roughly 40-60 nm compared to the roughened portions of the HSIO trace which may include a roughness of roughly 350-600 nm. Note that, for example, the surface roughness (or surface profile) may be a quantitative calculation of the relative roughness measured across an area of the surface (or the Cu surface), which may be determined via linear measurements of roughness through the area and/or several surface profiles that are averaged and reported (i.e., the surface roughness may be determined as an average of a surface profile through the Cu surface, and/or as the arithmetic average of the peak heights and valleys from a mean line of the surface).

Embodiments of the HSIO trace may include roughened portions such as adhesion anchoring points. As used herein, an “adhesion anchoring point” refers to a portion/point on a trace (e.g., HSIO traces 120-121) that has been subjected to the chemical treatment and, as such, this portion on the trace has a roughened Cu surface. The “adhesion anchoring point” may be formed on one or more portions of the HSIO traces 120-121 to mitigate with delamination and improve the adhesion processes, such as for build-up resin lamination, dry film lamination or solder mask application. In one embodiment, for roughly every trace length of 500 um on the HSIO trace (i.e., the measuring variable), a trace length of roughly 20 um may be roughened on the HSIO trace—and so on—to form the adhesion anchoring points (e.g., the total trace length of the adhesion anchoring points (or the roughened portions) may roughly be 4% or less of the total HSIO trace length). Note, however, that the trace length of the measuring variable may be greater than (or less than) 500 um based on the desired electrical characteristics of the HSIO trace, but the ratio of the roughened portions to the non-roughened portions has to be approximately 0.04 or less of the total length of the HSIO trace.

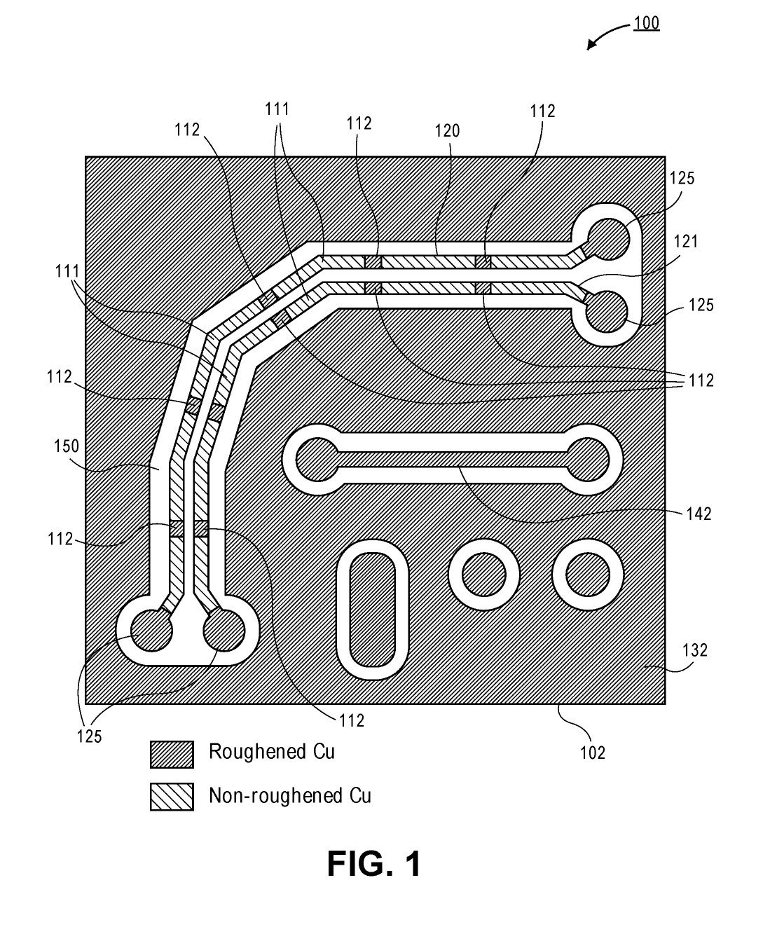

According to some embodiments, a semiconductor package (device/substrate) having one or more HSIO traces (i.e., traces with routing signals of roughly 28 GHz or higher) is described. For one embodiment, the HSIO trace is disposed on a conductive layer of the semiconductor package. For some embodiments, the HSIO trace is disposed between via pads and includes a plurality of non-roughened portions. Additionally, one or more adhesion anchoring points may be selectively disposed on the HSIO trace and between the non-roughened portions (e.g., the HSIO traces 120-121 as shown in FIG. 1).

Embodiments of the semiconductor package enhance packaging solutions by enabling a dielectric layer (e.g., a dry film resist) to cover the non-roughened portions of the HSIO trace during a Cu roughening treatment (e.g., the chemical treatment), as the HSIO trace roughness may maintain roughly the same roughness of the as-plated Cu of the HSIO trace (e.g., roughly 50 nm or less). Furthermore, the embodiments of the semiconductor package help to provide one or more adhesion anchoring points on the HSIO trace to provide adhesion anchoring between the Cu of the HSIO trace and the dielectric. The embodiments of semiconductor package improve packaging solution by reducing the insertion loss of the package without using adhesion promotion on the HSIO traces. This allows for these embodiments to improve the signal frequency of the HSIO routing and reduce the overall assembly time and cost of the semiconductor packages.

Additionally, the embodiments described herein improve semiconductor packaging by reducing insertion loss of a transmission line on a semiconductor package (or a package substrate). These embodiment further facilitate the foundation (or building blocks) needed to increase HSIO frequency in semiconductor packaging as the data transfer bandwidth of the semiconductor devices can be greatly increased. In addition, the embodiments of the semiconductor packages described below allow for a reduced Cu trace roughness that is similar to the roughness of the as-plated Cu surface (e.g., a roughness of roughly 50 nm or less) compared to, for example, using an adhesion promotion on the Cu trace which may have a roughness of roughly 100 to 150 nm. These embodiments also improve the insertion loss of packaging solutions without being limited to only dielectrics, thus these embodiments are not hindered by next-generation dielectric materials. Furthermore, these embodiments of the HSIO traces having non-roughened portions reduces: (i) the packaging complexity as a wet process typically used to control the thickness of the adhesion promotion is not required, and (ii) the packaging costs as no new packaging tools or additional assembly steps are needed.

Note that, for some alternative embodiments, while a chemical roughening process, for example, may be illustrated herein, a variety of other roughening processes may be suitable for trace roughening depending on the application and/or desired packaging design.

Lastly, the embodiments described herein provide techniques and mechanisms for reducing trace roughness in a substrate (e.g., a semiconductor package, a package substrate, a printed circuit board (PCB), etc.)—without adhesion promotion—to reduce the insertion loss of the substrate. A trace may include any type of conductive material including a Cu trace (or Cu seed layer), and the trace may also include a combination of one or more conductive materials (or metals).

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. Such devices may be portable or stationary. In some embodiments, the technologies described herein may be employed in a desktop computer, laptop computer, smart phone, tablet computer, netbook computer, notebook computer, personal digital assistant, server, combinations thereof, and the like. More generally, the technologies described herein may be employed in any of a variety of electronic devices including a substrate including interconnect structures to provide connectivity to integrated circuitry.

In the following description, various aspects of the illustrative implementations will be described using terms commonly employed by those skilled in the art to convey the substance of their work to others skilled in the art. However, it will be apparent to those skilled in the art that the present embodiments may be practiced with only some of the described aspects. For purposes of explanation, specific numbers, materials and configurations are set forth in order to provide a thorough understanding of the illustrative implementations. However, it will be apparent to one skilled in the art that the present embodiments may be practiced without the specific details. In other instances, well-known features are omitted or simplified in order not to obscure the illustrative implementations.

Various operations will be described as multiple discrete operations, in turn, in a manner that is most helpful in understanding the present embodiments, however, the order of description should not be construed to imply that these operations are necessarily order dependent. In particular, these operations need not be performed in the order of presentation.

FIG. 1 is a plan view of a semiconductor package 100 having a substrate 102 with a conductive layer 132 with HSIO traces 120-121, according to one embodiment. Furthermore, FIG. 1 illustrates a top view of a conductive layer 132 disposed on a substrate 102, where the substrate 102 may have a plurality of conductive layers (i.e., the conductive layer 132 may be a topmost layer, an intermediate layer, or a bottommost layer on the substrate 102).

For some embodiments, the semiconductor package 100 includes the substrate 102 but may also include one or more substrates, dies, interposers, etc., that are stacked (or coupled) to form the semiconductor package 100. According to some embodiments, the substrate 102 may include, but is not limited to, a package substrate, a substrate, a printed circuit board (PCB), and a motherboard. For one embodiment, the substrate 102 is a PCB. For one embodiment, the PCB is made of an FR-4 glass epoxy base with thin copper foil laminated on both sides. For certain embodiments, a multilayer PCB can be used, with pre-preg and copper foil used to make additional layers. For example, the multilayer PCB may include one or more dielectric layers, where each dielectric layer can be a photosensitive dielectric layer. For some embodiments, holes (not shown) may be drilled in the PCB 102. For one embodiment, the PCB 102 may also include conductive copper traces 120-121 and 142, metallic via pads 125, and holes.

For one embodiment, the conductive layer 132 includes a roughened Cu surface which may include the HSIO traces 120-121, a routing trace 142 (i.e., a trace with a frequency signal that is equal or less to 28 GHz), via pads 125, and a plane on the substrate 102. Note that, as shown in FIG. 1, a roughened Cu surface is illustrated with a first pattern (closely-spaced forward slashes/lines), and a non-roughened Cu surface is illustrated with a second pattern (wide-spaced back slashes/lines).

Referring back to FIG. 1, one or more HSIO traces 120-121 are disposed on the underlying layer 150 of the substrate 102. For one embodiment, each of the HSIO traces 120-121 is disposed between two via pads 125 on opposite ends. For one embodiment, the HSIO traces 120-121 have a plurality of non-roughened portions 111 (or a plurality of portions) and one or more adhesion anchoring points 112 (or a plurality of roughened portions). Each of the HSIO traces 120-121 has the non-roughened portions 111 disposed (or formed) between the one or more adhesion anchoring points 112. For example, the HSIO trace 120 may include at least two of the non-roughened portions 111 disposed between (or separated by) one of the adhesion anchoring points 112, which allows the HSIO trace 120 to periodically/selectively have these adhesion anchoring points (e.g., for every 500 um trace length, roughly a 20 um trace length may be roughened) to provide adhesion anchoring between the HSIO trace 120 and a dielectric (not shown). Accordingly, the substrate 102 also has the via pads 125, the Cu plane 132 (e.g., a Cu ground plane), and other lower frequency traces 142 that may still need to be roughened to avoid delamination between the respective Cu surfaces and the dielectric (not shown)—without adhesion promotion needed. Note that, even if the HSIO traces 120-121 are shown as two parallel and identical traces in FIG. 1, the HSIO traces may have any shape, any number of non-roughened portions, any number of adhesion anchoring points, and number of traces as may be needed based on the desired packaging design and/or application.

For to some embodiments, the substrate 102 has the conductive layer 132 disposed on the underlying layer 150 of the substrate 102, where the conductive layer 132 includes the roughened Cu in the pad/plane area, via pads 125, and routing trace 142 (note that this is excluding the non-roughened Cu portions 111 on the HSIO traces 120-121 on the conductive layer 132). For example, in one or more trace areas including data double rate (DDR) and power/ground trace areas, the Cu may be roughened. Alternatively, for the embodiments of the HSIO traces 120-121 (e.g., peripheral component interconnect express (PCIe) and fabric traces), the Cu on these HSIO traces 120-121 are not roughened aside from the periodic (or selective) adhesion anchoring points 111 that are roughened to mitigate delamination and improve adhesion between the Cu and the dielectric (not shown). For one embodiment, the one or more adhesion anchoring points 111 (i.e., the one or more portions of the HSIO traces 120-121 that are roughened periodically) may comprise of roughly 4% of the total HSIO trace length (e.g., this percentage may be changed based on the desired packaging design, application, or frequency), as the impact of these adhesion anchoring points 111 on the overall insertion loss of the semiconductor package 100 may be negligible.

Accordingly, some of the advantages of the HSIO traces with the non-roughened portions (e.g., as shown with HSIO traces 120-121) is that (i) the trace roughness can be further reduced by roughly 50% or greater (e.g., reduced from a roughness of 150-100 nm to 50 nm or less), (ii) the trace roughness reduction process is cost-efficient as the process does not require any new equipment, materials, and etc., (iii) the process development time can be greatly reduced, and (iv) the reliability risk of the overall process is reduced (i.e., reduced uncertainty as compared to, for example, the reliability risk of using adhesion promotion, which is higher and not fully understood).

Note that the semiconductor package 100 of FIG. 1 may include fewer or additional packaging components based on the desired packaging design.

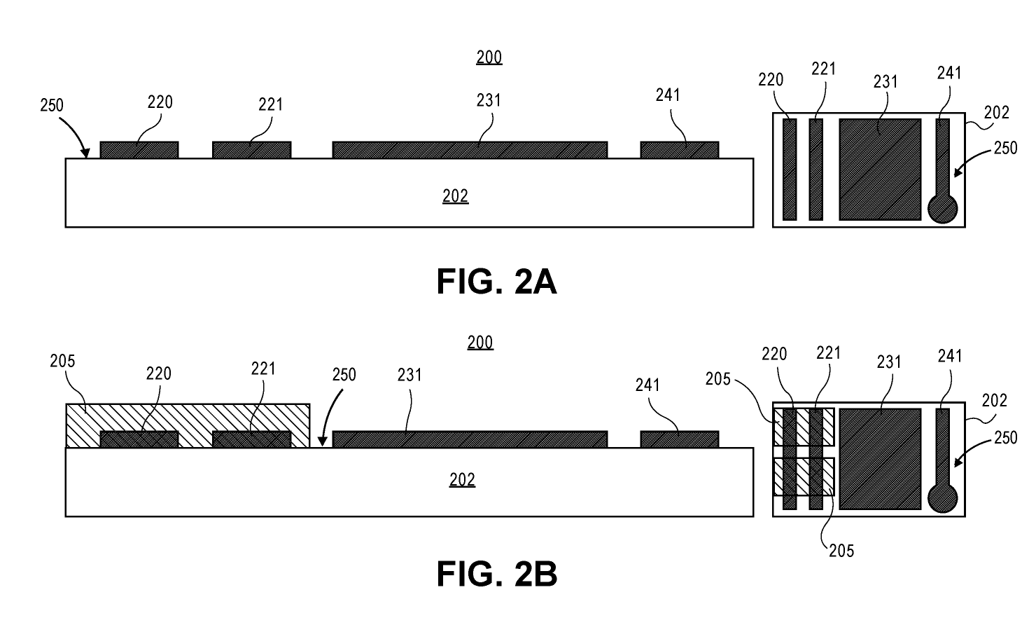

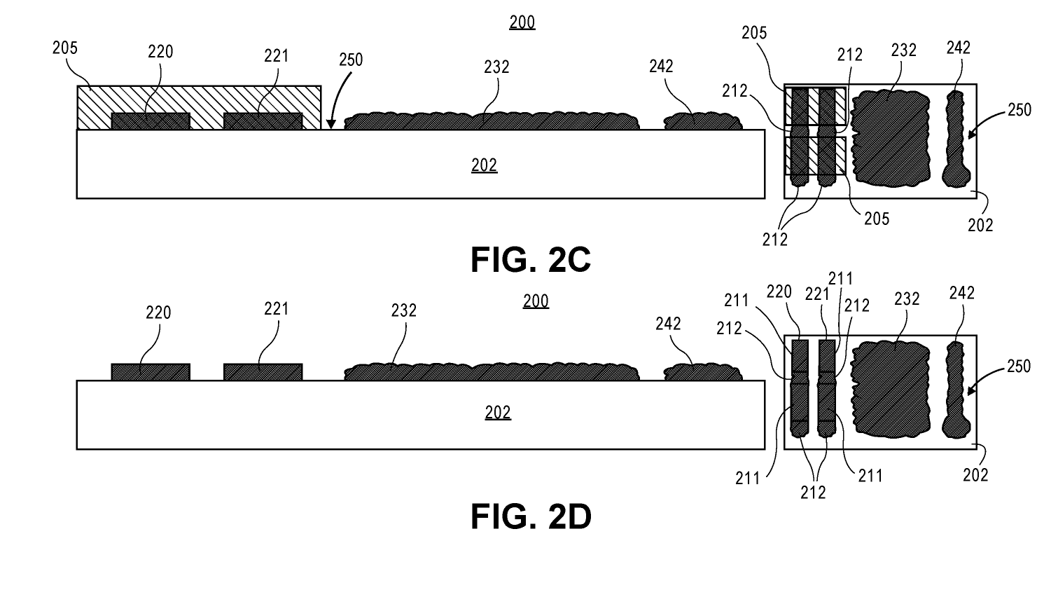

FIGS. 2A-2D are cross-sectional views and the respective plan views of a process flow 200 to form a semiconductor package (or a package layer) having a conductive layer with HSIO traces with adhesion anchoring points, according to some embodiments. These embodiments as shown with respect to FIGS. 2A-2D provide the process flow 200 that enables non-roughened portions and selective adhesion anchoring points on HSIO traces that are used to reduce insertion loss of HSIO routing in a substrate of a semiconductor package. For one embodiment, the HSIO traces 220-221 of the semiconductor package shown in FIG. 2D are similar to the HSIO traces 120-121 of the semiconductor package 100 of FIG. 1.

One such embodiment is illustrated and described based on FIGS. 2A-2D, which illustrates cross-sectional views and their respective plan views of a package layer used to form non-roughened portions on a HSIO trace—while one or more adhesion anchoring points are also patterned on the HSIO trace. As such, FIGS. 2A-2D show the process flow 200 enabling selective roughened Cu on a package layer to reduce the insertion loss of the HSIO routing of the substrate. Note that FIGS. 2A-2D illustrate the selective roughened Cu process flow 200 (or the selective Cu roughening process flow) implemented on HSIO traces (e.g., HSIO traces 220-221), however the selective roughened Cu process flow 200 may be implemented on other conductive materials, traces, planes, vias, etc., that need to reduce insertion loss.

Each of FIGS. 2A-2D illustrates a cross-sectional view (on the left) and a respective top-view (on the right) of the package layer, where these respective views help to show the disposition and pattering of a dielectric layer on the HSIO traces. In the illustrated embodiments, the disposition and patterning of the dielectric layer on the HSIO is shown, however it is to be appreciated that additional features, such as additional components, traces, planes, holes, layers, lines, vias, and/or pads, may be formed at the same time and with the same processing operations, according to the embodiments described herein.

Referring back to FIG. 2A, a process flow 200 shows a package layer having a substrate 202, HSIO traces 220-221, a conductive plane 231, and a trace 241. For one embodiment, the process flow 200 illustrates disposing (or forming) a conductive layer on an underlying layer 250 of the substrate 202, where the conductive layer includes, but is not limited to, the HSIO traces 220-221, the conductive plane 231 (e.g., a ground plane), and the trace 241. For some embodiments, the substrate 202 may be similar to the substrate 102 of FIG. 1. Note that the conductive layer only shows portions of the HSIO traces, conductive plane, and trace, but the conductive layer may include additional packaging components (e.g., additional HSIO traces) based on the desired packaging design.

FIG. 2B illustrates the process flow 200 patterning a dielectric layer 205 on the HSIO traces 220-221, where the dielectric layer 205 is patterned on/over a plurality of non-roughened portions of the HSIO traces 220-221. For one embodiment, as shown in the top view of the package layer, the dielectric layer 205 is patterned on the plurality of non-roughened portions to form one or more exposed openings on the HSIO traces 220-221. For example, the one or more openings are periodically (or selectively) formed on the HSIO traces 220-221, where the one or more openings are exposed on the HSIO traces 220-221 to subsequently form adhesion anchoring points by implementing a roughening process (e.g., after disposing a chemical treatment on the one or more exposed openings, the Cu of the exposed openings is roughened with the chemical treatment to form the adhesion anchoring points 212 as shown in FIGS. 2C-2D).

For some embodiments, the dielectric layer 205 may be a polymer material, such as, but not limited to, a dry film resist (DFR), a polyimide, an epoxy, or a build-up film (BF). In one embodiment, the dielectric layer 205 may be one layer in a stack that includes a plurality of dielectric layers used to form a build-up structure. As such, the dielectric layer 205 may be formed over another dielectric layer. Additional embodiments may include disposing the dielectric layer 205 as the first dielectric layer over a core material on which the stack is formed. For one embodiment, the dielectric layer 205 is disposed and patterned on the HSIO traces 220-221 to provide the openings for the formation of the adhesion anchoring points (i.e., the roughened portions) on the HSIO traces 220-221. For some embodiments, the overall length of the non-roughened portions is greater than the overall length of the exposed openings on the HSIO traces 220-221 (e.g., for every 500 um length of a HSIO trace, roughly 20 um may be exposed).

FIG. 2C illustrates the process flow 200 exposing the conductive layer (i.e., the exposed Cu on the substrate 202) with a chemical treatment to form adhesion anchoring points 212 (i.e., roughened small points/portions on the HSIO traces 220-221), roughened conductive plane 232, and roughened trace 242. For one embodiment, the conductive layer on the substrate 202 is roughened only on the exposed Cu surfaces—including the anchoring points 212, roughened conductive plane 232, and roughened trace 242—while the remaining portions of the HSIO traces 220-221 that are not exposed and covered with the dielectric layer 205 remain as non-roughened portions (e.g., non-roughened portions 211 as shown in FIG. 2D). Note that, as shown in FIG. 2C, the roughened Cu surfaces/portions of the conductive layer are illustrated with wavy outer edges.

FIG. 2D illustrates the process flow 200 removing (or stripping) the dielectric layer 205 to expose a plurality of non-roughened portions 211 on the HSIO traces 220-221. According to some embodiments, as shown in FIG. 2D, the semiconductor package includes the conductive layer disposed (or formed) on the substrate 202, where the dielectric layer 205 is removed to expose the non-roughened portions 211 of the HSIO traces 220-221 that are separated by the adhesion anchoring points 212. For one embodiment, the dielectric removal process may include a wet etch, a dry etch (e.g., a plasma etch), a wet blast, or a laser ablation (e.g., by using excimer laser).

As shown with the top view of FIG. 2D, the conductive layer has an overall roughened surface area, which includes the roughened points/planes/traces 211, 232, and 242, that is larger than an overall non-roughened surface area, which includes the non-roughened portions 211 on the HSIO traces 220-221. For one embodiment, a build-up film (not shown) may be disposed on (or surrounding) the HSIO traces 220-221 of the substrate 202, which helps to eliminate delamination between HSIO traces 220-221 (i.e., Cu traces) and the build-up film. Note that the conductive layer of the substrate 202 only has some portions that are not roughened. For these embodiments, the HSIO traces 220-221 may be surrounded with the build-up film material (e.g., ABF material) on both the non-roughened portions 211 and the adhesion anchoring points 212. Accordingly, even if there may be a lower adhesion between the non-roughened portions 211 of the HSIO traces 220-221 and the build-up film, the delamination between the non-roughened Cu portions 211 to the build-up film does not propagate in the lateral direction (i.e., along the trace width direction) as the build-up film holds the HSIO traces 220-221 in place. Likewise, along the trace length direction, the HSIO traces 220-221 have periodical roughened Cu of the anchoring adhesion points 211 to prevent the delamination to propagate.

These embodiments as illustrated in FIGS. 2A-2D enable the HSIO traces 220-221 to have a plurality of non-roughened portions 211 and selective adhesion anchoring points 212. For some embodiments, as shown with FIGS. 2A-2D, the process flow 200 shows a method of forming a semiconductor package that may include disposing the conductive layer (e.g., HSIO traces 220-221, plane 231, and trace 241) on the substrate 202, where the conductive layer has a trace (e.g., HSIO trace 220); disposing the dielectric 205 on the trace; patterning the dielectric 205 to form one or more exposed openings (e.g., the exposed openings that form the roughened, adhesion anchoring points 212) and the plurality of non-roughened portions 211 on the trace, where the dielectric 205 only covers the plurality of non-roughened portions 212, as such the one or more exposed openings on the trace are exposed and not covered by the dielectric 205; disposing a chemical treatment on the conductive layer and the one or more exposed openings to form the one or more adhesion anchoring points 212; and removing the dielectric 205 to expose the plurality of non-roughened portions 211 on the trace.

Accordingly, the non-roughened portions 211 of the HSIO traces 220-221 thus provide a reduced insertion loss on the transmission signals of the HSIO traces 220-221 on the substrate 202, which also helps to reduce assembly time and costs by circumventing the need for adhesion promotion. In addition, these embodiments as illustrated with the process flow of FIGS. 2A-2D help to improve semiconductor packaging by (i) reducing the roughness of the high-speed input/output routing (e.g., a roughness of roughly 50 nm or less) that enables a reduced insertion loss for the semiconductor package; and (ii) reducing (or simplifying) the time and cost of the assembly process and the reliability risk.

Note that the process flow as shown with FIGS. 2A-2D may include fewer or additional packaging components and steps based on the desired packaging design.

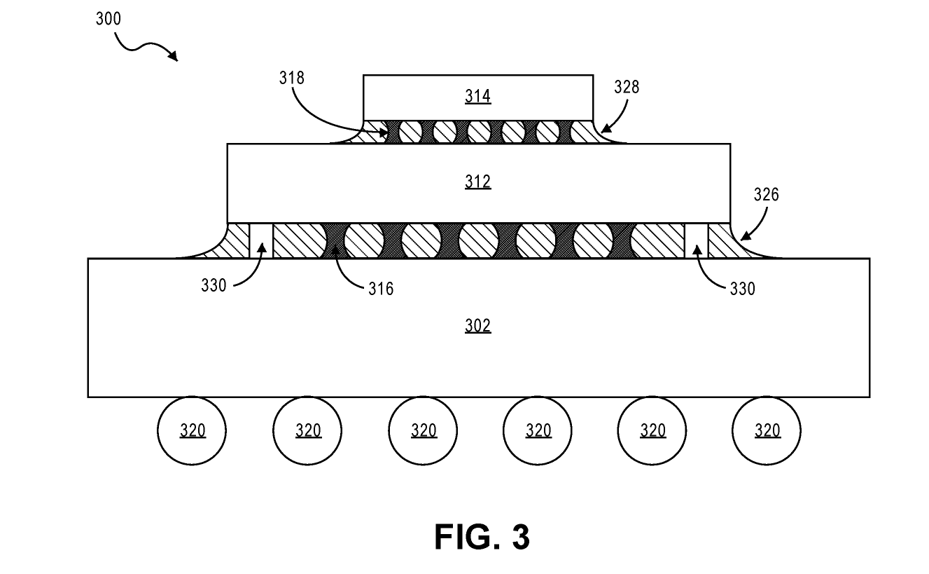

FIG. 3 is a cross-sectional view of a semiconductor package 300 having a package substrate 302 that may include a conductive layer with a HSIO trace, where the HSIO trace has a plurality of non-roughened portions and one or more adhesion anchoring points, according to one embodiment. Specifically, FIG. 3 illustrates the semiconductor package 300 including a stacked package with interconnect structures (e.g., the plurality of bumps disposed below a die 314 and an interposer 312) and the package substrate 302 having one or more conductive layers that may include one or more HSIO traces, according to some embodiments. For one embodiment, the semiconductor package 300 may include a conductive layer that has one or more HSIO traces (e.g., HSIO traces 120-121 as shown in FIG. 1) that include non-roughened portions and adhesion anchoring points (as shown in FIGS. 1-2). Note that the package substrate 302 may be similar to the substrate 102 of FIG. 1 and the substrate 202 of FIGS. 2A-2D.

For one embodiment, the semiconductor package 300 includes a HSIO trace formed/disposed on a conductive layer of the package substrate 302, one or more adhesion anchoring points disposed on the HSIO trace, and a plurality of non-roughened portions on the HSIO trace, where at least one of the adhesion anchoring points is disposed between at least two of the non-roughened portions of the HSIO trace.

According to one embodiment, the semiconductor package 300 is merely one example of an embodiment wherein an integrated circuit die 314 is coupled to a substrate 312 (e.g., an interposer) via one or more bumps/joints formed from respective microbumps. As described above, a solder joint formed by soldering of a microbump according to an embodiment may itself be referred to as a “bump” and/or a “microbump.”

For some embodiments, the semiconductor package 300 may have a die 314 disposed on an interposer 312, where both the stacked die 314 and interposer 312 are disposed on a package substrate 302. According to some embodiments, the package substrate 302 may include, but is not limited to, a package, a substrate, a printed circuit board (PCB), and a motherboard. For one embodiment, the package substrate 302 is a PCB. For one embodiment, the PCB is made of an FR-4 glass epoxy base with thin copper foil laminated on both sides (not shown). For certain embodiments, a multilayer PCB can be used, with pre-preg and copper foil (not shown) used to make additional layers. For example, the multilayer PCB may include one or more dielectric layers, where each dielectric layer can be a photosensitive dielectric layer (not shown). For some embodiments, holes (not shown) may be drilled in the PCB 302. For one embodiment, the PCB 302 may also include conductive copper traces, metallic pads, and holes (not shown).

For one embodiment, the die 314 may include, but is not limited to, a semiconductor die, an electronic device (e.g., a wireless device), an integrated circuit, a central processing unit (CPU), a microprocessor, a platform controller hub (PCH), a memory, and a field-programmable gate array (FPGA). The die 314 may be formed from a material such as silicon and have circuitry thereon that is to be coupled to the interposer 312. Although some embodiments are not limited in this regard, the package substrate 302 may in turn be coupled to another body, for example, a computer motherboard (not shown). One or more connections between the package substrate 302, the interposer 312, and the die 314—e.g., including some or all of bumps 316, 318, and 320—may include one or more interconnect structures and underfill layers 326 and 328. In some embodiments, these interconnect structures (or connections) may variously comprise an alloy of nickel, palladium, and tin (and, in some embodiments, Cu).

Connections between the package substrate 302 and another body may be made using any suitable structure, such as the illustrative bumps 320 shown. The package substrate 302 may include a variety of electronic structures formed thereon or therein. The interposer 312 may also include electronic structures formed thereon or therein, which may be used to couple the die 314 to the package substrate 302. For one embodiment, one or more different materials may be used for forming the package substrate 302 and the interposer 312. In certain embodiments, the package substrate 302 is an organic substrate made up of one or more layers of polymer base material, with conducting regions for transmitting signals. In certain embodiments, the interposer 312 is made up of a ceramic base material including metal regions for transmitting signals. Although some embodiments are not limited in this regard, the semiconductor package 300 may include gap control structures 330—e.g., positioned between the package substrate 310 and the interposer 312. Such gap control structures 330 may mitigate a change in the height of the gap between the package substrate 302 and the interposer 312, which otherwise might occur during reflowing while die 314 is attached to interposer 312. Note that the semiconductor package 300 includes an underflow material 328 between the interposer 312 and the die 314, and an underflow material 326 between the package substrate 302 and the interposer 312. The underflow materials (or layers) 326 and 328 may be one or more polymers that are injected between the layers.

Note that the semiconductor package 300 may include fewer or additional packaging components based on the desired packaging design.

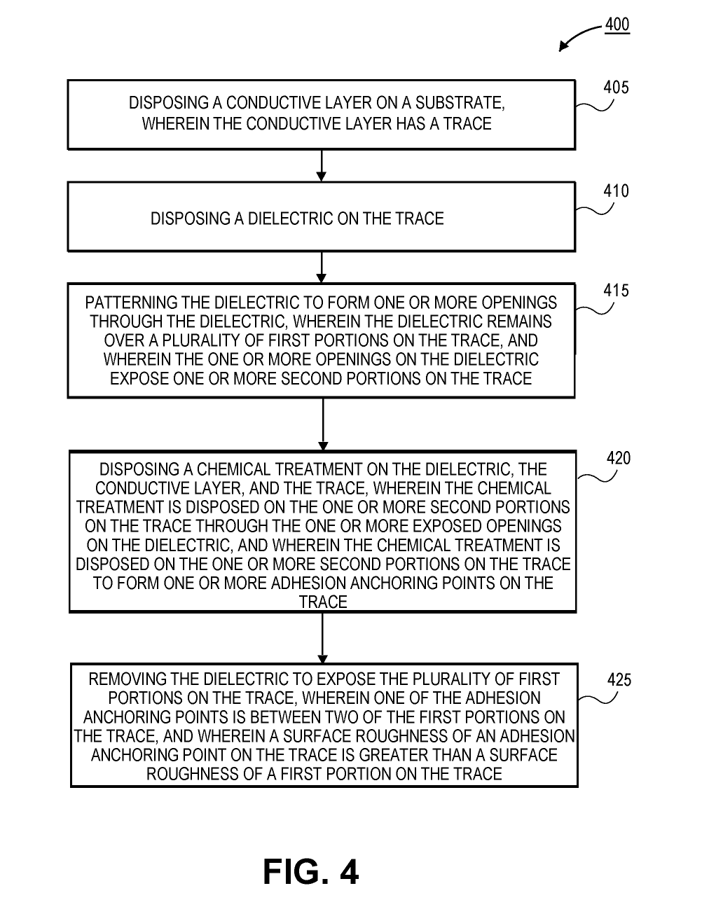

FIG. 4 is a process flow 400 illustrating a method of a semiconductor package having a substrate which includes a conductive layer with a HSIO trace, where the HSIO trace has a plurality of portions and one or more adhesion anchoring points, according to one embodiment. For one embodiment, the process flow 400 includes one or more steps used to form the semiconductor packages as described herein (e.g., the semiconductor packages 100 of FIG. 1, 200 of FIGS. 2A-2D, and 300 of FIG. 3). According to one embodiment, the process flow 400 may be similar to the process flow illustrated with FIGS. 2A-2D. Specifically, the process flow 400 may be used to form a HSIO trace (e.g., HSIO traces 220-221 of FIG. 2D) that has non-roughened portions (e.g., non-roughened portions 211 of FIG. 2D) and adhesion anchoring points (e.g., adhesion anchoring points 212 of FIG. 2D), according to one embodiment.

At block 405, the process flow 400 disposes a conductive layer on a substrate, where the conductive layer has a trace (e.g., as shown in FIG. 2A). At block 410, the process flow 400 disposes a dielectric on the trace (e.g., as shown in FIG. 2B). At block 415, the process flow 400 patterns the dielectric to form one or more openings through the dielectric, where the dielectric remains over a plurality of first portions on the trace, and where the one or more openings on the dielectric expose one or more second portions on the trace (e.g., as shown in FIG. 2B). At block 420, the process flow 400 disposes a chemical treatment on the dielectric, the conductive, and the trace, where the chemical treatment is disposed on the one or more second portions on the trace through the one or more exposed openings on the dielectric, and where the chemical treatment is disposed on the one or more second portions on the trace to form one or more adhesion anchoring points on the trace (e.g., as shown in FIG. 2C). At block 425, the process flow 400 removes the dielectric to expose the plurality of first portions on the trace (i.e., the non-roughened portions on the trace), where one of the adhesion anchoring points is between two of the first portions on the trace, and wherein a surface roughness of an adhesion anchoring point (i.e., a roughened portion) on the trace is greater than a surface roughness of a first portion on the trace (e.g., as shown in FIG. 2D).

For additional embodiments, the process flow may have trace be a HSIO trace. Additionally, the process flow may include the conductive layer which has a plane and a second trace (e.g., as shown in FIG. 2D). The embodiments of the process flow may include disposing one or more via pads on each end of the trace (e.g., as shown in FIG. 1). The process flow may have the chemical treatment disposed on the conductive layer to form a roughened plane, a roughened trace, and one or more roughened surfaces (e.g., as shown in FIG. 1). In one embodiment, the process flow may implement the portions to reduce an insertion loss on the trace (and/or the semiconductor package). For one embodiment, the process flow may have the dielectric comprising a polymer material. Additionally, the process flow may include disposing a build-up film on the conductive layer, where the build-up film attaches to the adhesion anchoring points on the trace of the conductive layer. For alternative embodiments, the process flow may pattern a material surface to have a roughened portion and a non-roughened portion (or an as-plated material surface (i.e., the material surface is not altered, treated, etc.)), as the material surface includes, but not limited to, any desired conductive materials (i.e., the process flow is not limited to Cu and may be used on any desired conductive material based on the packaging application and need).

Note that the semiconductor package formed by process flow 400 may include fewer or additional packaging components based on the desired packaging design (e.g., as shown in FIGS. 1-3).

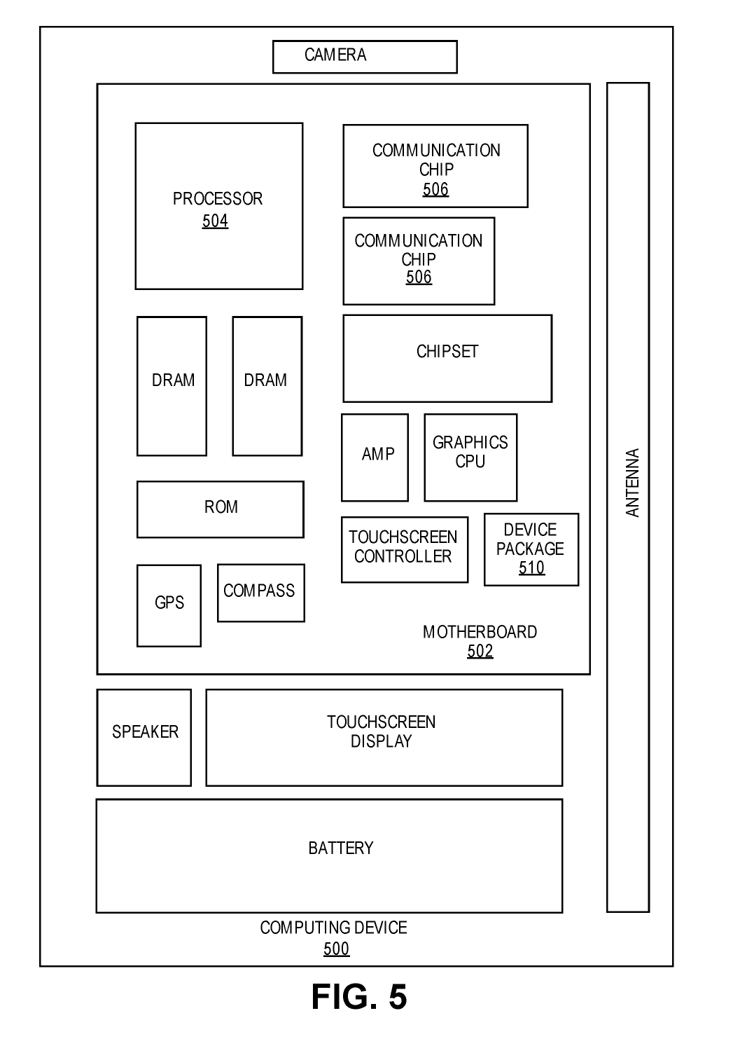

FIG. 5 is a schematic block diagram illustrating a computer system that utilizes a semiconductor package having a substrate which includes a conductive layer with a HSIO trace, where the HSIO trace has a plurality of non-roughened portions and one or more adhesion anchoring points, according to one embodiment. FIG. 5 illustrates an example of computing device 500. Computing device 500 houses motherboard 502. For one embodiment, motherboard 502 may be similar to the substrates of FIGS. 1-3 (e.g., substrates 102 of FIG. 1, 202 of FIGS. 2A-2D, and 302 of FIG. 3). Motherboard 502 may include a number of components, including but not limited to processor 504, device package 510 (or semiconductor package), and at least one communication chip 506. Processor 504 is physically and electrically coupled to motherboard 502. For some embodiments, at least one communication chip 506 is also physically and electrically coupled to motherboard 502. For other embodiments, at least one communication chip 506 is part of processor 504.

Depending on its applications, computing device 500 may include other components that may or may not be physically and electrically coupled to motherboard 502. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

At least one communication chip 506 enables wireless communications for the transfer of data to and from computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. At least one communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 500 may include a plurality of communication chips 406. For instance, a first communication chip 406 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

Processor 504 of computing device 500 includes an integrated circuit die packaged within processor 504. Device package 510 may be, but is not limited to, a package, a substrate, and/or a printed circuit board. Device package 510 may be a semiconductor package that includes a conductive layer with a HSIO trace, where the HSIO trace has a plurality of non-roughened portions and one or more adhesion anchoring points (as illustrated in FIGS. 1-4)—or any other components from the figures described herein—of the computing device 500. Further, as described herein, the device package 510 helps reduce the insertion loss of the computing device 500 (e.g., the insertion loss improvement may roughly be 1.2 dB above other packaging solutions)—without requiring adhession promotion—by enabling HSIO traces to have non-roughened portions that reduce the overall roughness of the HSIO traces (e.g., reduce to a roughness of roughly 50 um or less that may be equivalent to the roughness of the as-plated Cu of the HSIO trace). Accordingly, the device package 510 faciliates and improves the computing device 500 by (i) reducing the overall roughness of the HSIO traces, (ii) reducing assembly costs and time (as the process flow used to form the HSIO traces do not necessitate additional equipment, material sets, and/or recipes), and (iii) providing a reduced reliability risk (as the reliability risk for adhesion promotion is still being developed and thus not fully understood).

Note that device package 510 may be a single component/device, a subset of components, and/or an entire system, as the materials, features, and components may be limited to device package 510 and/or any other component of the computing device 500 that may need traces having non-roughened portions and adhesion anchoring points (e.g., the motherboard 502 and/or any other component of the computing device 500 may have HSIO traces as described herein).

For certain embodiments, the integrated circuit die may be packaged with one or more devices on a package substrate that includes a thermally stable RFIC and antenna for use with wireless communications and the device package, as described herein, to reduce the z-height of the computing device. The term “processor” may refer to any device or portion of a device that processes electronic data from registers and/or memory to transform that electronic data into other electronic data that may be stored in registers and/or memory.

At least one communication chip 506 also includes an integrated circuit die packaged within the communication chip 506. For some embodiments, the integrated circuit die of the communication chip may be packaged with one or more devices on a package substrate that includes one or more device packages, as described herein.

In the foregoing specification, embodiments have been described with reference to specific exemplary embodiments thereof. It should be borne in mind, however, that all of these and similar terms are to be associated with the appropriate physical quantities and are merely convenient labels applied to these quantities. It will be evident that various modifications may be made thereto without departing from the broader spirit and scope. The specification and drawings are, accordingly, to be regarded in an illustrative sense rather than a restrictive sense.

The following examples pertain to further embodiments. The various features of the different embodiments may be variously combined with some features included and others excluded to suit a variety of different applications.

The following examples pertain to further embodiments:

Example 1 is a semiconductor package, comprising: a trace on a conductive layer; one or more adhesion anchoring points on the trace; and a plurality of portions on the trace. One of the adhesion anchoring points is disposed between two of the portions. A a surface roughness of an adhesion anchoring point is greater than a surface roughness of a portion.

In example 2, the subject matter of example 1 can optionally include a trace that is a high-speed input/output (HSIO) trace.

In example 3, the subject matter of any of examples 1-2 can optionally include the conductive layer disposed on an underlying layer of a substrate. The conductive layer further includes a plane and a second trace.

In example 4, the subject matter of any of examples 1-3 can optionally include one or more via pads disposed on each end of the trace; a dielectric disposed on the trace. The dielectric is patterned on the plurality of portions of the trace; and one or more openings on the dielectric are patterned to expose one or more second portions on the trace. The dielectric only covers the plurality of portions on the trace. The one or more exposed second portions on the trace form the one or more adhesion anchoring points.

In example 5, the subject matter of any of examples 1-4 can optionally include at least one of the plane and the second trace have a surface roughness greater than the surface roughness of the portion on the trace.

In example 6, the subject matter of any of examples 1-5 can optionally include the plurality of portions reduce an insertion loss on the trace.

In example 7, the subject matter of any of examples 1-6 can optionally include the dielectric includes a polymer material.

In example 8, the subject matter of any of examples 1-7 can optionally include a build-up film disposed on the conductive layer. The build-up film attaches to the adhesion anchoring points on the trace of the conductive layer.

Example 9 is a method of forming a semiconductor package, comprising: disposing a conductive layer on a substrate, wherein the conductive layer has a trace; disposing a dielectric on the trace; patterning the dielectric to form one or more openings through the dielectric. The dielectric remains over a plurality of first portions on the trace. The one or more openings on the dielectric expose one or more second portions on the trace; disposing a chemical treatment on the dielectric, the conductive layer, and the trace. The chemical treatment is disposed on the one or more second portions on the trace through the one or more exposed openings on the dielectric. The chemical treatment is disposed on the one or more second portions on the trace to form one or more adhesion anchoring points on the trace; and removing the dielectric to expose the plurality of first portions on the trace. One of the adhesion anchoring points is between two of the first portions on the trace. A surface roughness of an adhesion anchoring point on the trace is greater than a surface roughness of a first portion on the trace.

In example 10, the subject matter of example 9 can optionally include the trace is a HSIO trace.

In example 11, the subject matter of any of examples 9-10 can optionally include the conductive layer which further includes a plane, a second trace, and one or more surfaces.

In example 12, the subject matter of any of examples 9-11 can optionally include disposing one or more via pads on each end of the trace;

In example 13, the subject matter of any of examples 9-12 can optionally include the chemical treatment disposed on the plane, the second trace, and the one or more surfaces of the conductive layer forms a roughened plane, a roughened trace, and one or more roughened surfaces.

In example 14, the subject matter of any of examples 9-13 can optionally include the plurality of first portions reduce an insertion loss on the trace.

In example 15, the subject matter of any of examples 9-14 can optionally include the dielectric includes a polymer material.

In example 16, the subject matter of any of examples 9-15 can optionally include disposing a build-up film on the conductive layer. The build-up film attaches to the adhesion anchoring points on the trace of the conductive layer.

Example 17 is a semiconductor package, comprising: an interposer on a substrate; a die on the interposer; a conductive layer on the substrate; and a trace on the conductive layer. The trace has one or more adhesion anchoring points and a plurality of portions. One of the adhesion anchoring points is disposed between two of the portions. A surface roughness of an adhesion anchoring point is greater than a surface roughness of a portion.

In example 18, the subject matter of example 17 can optionally include the trace is a HSIO trace.

In example 19, the subject matter of any of examples 17-18 can optionally include the conductive layer disposed on an underlying layer of the substrate. The conductive layer further includes a plane and a second trace.

In example 20, the subject matter of any of examples 17-19 can optionally include one or more via pads disposed on each end of the trace; a dielectric disposed on the trace. The dielectric is patterned on the plurality of portions of the trace; one or more openings on the dielectric are patterned to expose one or more second portions on the trace. The dielectric only covers the plurality of portions on the trace. The one or more exposed second portions on the trace form the one or more adhesion anchoring points; and a build-up film disposed on the conductive layer. The build-up film attaches to the adhesion anchoring points on the trace of the conductive layer.

In example 21, the subject matter of any of examples 17-20 can optionally include at least one of the plane and the second trace have a surface roughness greater than the surface roughness of the portion on the trace. The dielectric includes a polymer material.

In example 22, the subject matter of any of examples 17-21 can optionally include the plurality of portions reduce an insertion loss on the trace.

In example 23, the subject matter of any of examples 17-22 can optionally include the substrate which includes a package and a printed circuit board.

In example 24, the subject matter of any of examples 17-23 can optionally include the die which includes an integrated circuit, a central processing unit, a microprocessor, a platform controller hub, a memory, and a field-programmable gate array.

In example 25, the subject matter of any of examples 17-24 can optionally include a plurality of HSIO traces that have a plurality of portions and a plurality of adhesion anchoring points. Each HSIO trace has the plurality of adhesion anchoring points disposed between the plurality of portions.

In the foregoing specification, methods and apparatuses have been described with reference to specific exemplary embodiments thereof. It will be evident that various modifications may be made thereto without departing from the broader spirit and scope. The specification and drawings are, accordingly, to be regarded in an illustrative sense rather than a restrictive sense.

What is claimed is:

1. A semiconductor package, comprising:
a trace on a conductive layer;
one or more adhesion anchoring points on the trace; and
a plurality of portions on the trace, wherein one of the adhesion anchoring points is disposed between two of the portions, and wherein a surface roughness of an adhesion anchoring point is greater than a surface roughness of a portion.

2. The semiconductor package of claim 1, wherein trace is a high-speed input/output (HSIO) trace.

3. The semiconductor package of claim 1, wherein the conductive layer is disposed on an underlying layer of a substrate, and wherein the conductive layer further includes a plane and a second trace.

4. The semiconductor package of claim 1, further comprising:
one or more via pads disposed on each end of the trace;
a dielectric disposed on the trace, wherein the dielectric is patterned on the plurality of portions of the trace; and
one or more openings on the dielectric are patterned to expose one or more second portions on the trace, wherein the dielectric only covers the plurality of portions on the trace, wherein the one or more exposed second portions on the trace form the one or more adhesion anchoring points.

5. The semiconductor package of claim 3, wherein at least one of the plane and the second trace have a surface roughness greater than the surface roughness of the portion on the trace.

6. The semiconductor package of claim 1, wherein the plurality of portions reduce an insertion loss on the trace.

7. The semiconductor package of claim 4, wherein the dielectric includes a polymer material.

8. The semiconductor package of claim 1, further comprising a build-up film disposed on the conductive layer, wherein the build-up film attaches to the adhesion anchoring points on the trace of the conductive layer.

9. A method of forming a semiconductor package, comprising:
disposing a conductive layer on a substrate, wherein the conductive layer has a trace;
disposing a dielectric on the trace;
patterning the dielectric to form one or more openings through the dielectric, wherein the dielectric remains over a plurality of first portions on the trace, and wherein the one or more openings on the dielectric expose one or more second portions on the trace;
disposing a chemical treatment on the dielectric, the conductive layer, and the trace, wherein the chemical treatment is disposed on the one or more second portions on the trace through the one or more exposed openings on the dielectric, and wherein the chemical treatment is disposed on the one or more second portions on the trace to form one or more adhesion anchoring points on the trace; and
removing the dielectric to expose the plurality of first portions on the trace, wherein one of the adhesion anchoring points is between two of the first portions on the trace, and wherein a surface roughness of an adhesion anchoring point on the trace is greater than a surface roughness of a first portion on the trace.

10. The method of claim 9, wherein trace is a HSIO trace.

11. The method of claim 9, wherein the conductive layer further includes a plane, a second trace, and one or more surfaces.

12. The method of claim 9, further comprising disposing one or more via pads on each end of the trace;

13. The method of claim 11, wherein the chemical treatment disposed on the plane, the second trace, and the one or more surfaces of the conductive layer forms a roughened plane, a roughened trace, and one or more roughened surfaces.

14. The method of claim 9, wherein the plurality of first portions reduce an insertion loss on the trace.

15. The method of claim 9, wherein the dielectric includes a polymer material.

16. The method of claim 9, further comprising disposing a build-up film on the conductive layer, wherein the build-up film attaches to the adhesion anchoring points on the trace of the conductive layer.

17. A semiconductor package, comprising:
an interposer on a substrate;
a die on the interposer;
a conductive layer on the substrate; and
a trace on the conductive layer, wherein the trace has one or more adhesion anchoring points and a plurality of portions, wherein one of the adhesion anchoring points is disposed between two of the portions, and wherein a surface roughness of an adhesion anchoring point is greater than a surface roughness of a portion.

18. The semiconductor package of claim 17, wherein trace is a HSIO trace.

19. The semiconductor package of claim 17, wherein the conductive layer is disposed on an underlying layer of the substrate, and wherein the conductive layer further includes a plane and a second trace.

20. The semiconductor package of claim 17, further comprising:
one or more via pads disposed on each end of the trace;
a dielectric disposed on the trace, wherein the dielectric is patterned on the plurality of portions of the trace;
one or more openings on the dielectric are patterned to expose one or more second portions on the trace, wherein the dielectric only covers the plurality of portions on the trace, wherein the one or more exposed second portions on the trace form the one or more adhesion anchoring points; and
a build-up film disposed on the conductive layer, wherein the build-up film attaches to the adhesion anchoring points on the trace of the conductive layer.

21. The semiconductor package of claim 20, wherein at least one of the plane and the second trace have a surface roughness greater than the surface roughness of the portion on the trace, and wherein the dielectric includes a polymer material.

22. The semiconductor package of claim 17, wherein the plurality of portions reduce an insertion loss on the trace.

23. The semiconductor package of claim 17, wherein the substrate includes a package and a printed circuit board.

24. The semiconductor package of claim 17, wherein the die includes an integrated circuit, a central processing unit, a microprocessor, a platform controller hub, a memory, and a field-programmable gate array.

25. The semiconductor package of claim 18, further comprising a plurality of HSIO traces that have a plurality of portions and a plurality of adhesion anchoring points, wherein each HSIO trace has the plurality of adhesion anchoring points disposed between the plurality of portions.
